(19) United States
(12) Patent Application Publication
(10) Pub. No.: US 2026/0057151 A1
(43) Pub. Date: Feb. 26, 2026

(54) AUTOMATED MODEL BASED GUIDED DIGITAL TWIN SYNCHRONIZATION

(71) Applicant: Siemens Corporation, Washington, WA (US)

(72) Inventors: Spondon Kundu, Livingston, NJ (US); Aditi Roy, Plainsboro, NJ (US)

(73) Assignee: Siemens Corporation, Washington, WA (US)

(21) Appl. No.: 19/103,718

(22) PCT Filed: Aug. 23, 2022
(86) PCT No.: PCT/US2022/041191

§ 371 Date: Feb. 13, 2025

(51) Int. Cl. G06F 30/27

(52) U.S. Cl. CPC G06F 30/27

(57) ABSTRACT

An automated model based guided digital twin synchronization system is described. The system comprises visual sensors configured to acquire raw visual data of a physical 3D scene content from a real site, a database to provide a 3D model of the physical 3D scene content, a processor and a memory for storing computer-executable instructions executed by the processor. The instructions comprise an automated machine learning model based logic to: generate and maintain an as-built digital twin of the assets and large-scale infrastructures present in the physical 3D scene by ingesting the raw visual data to a common and binding structured representation, compare the as-built digital twin representation obtained from the real site against corresponding an as-planned digital twin to determine spatio-temporal differences between the as-built and the as-planned digital twins, and update automatically the as-planned digital twin to reflect any changes to the physical 3D scene based on the spatio-temporal differences.

### BACKGROUND

### 1. Field

Aspects of the present invention generally relate to an automated model-based guided digital twin synchronization system and a method for synchronizing a digital twin representation with a physical 3D scene.

### 2. Description of the Related Art

Before developing a factory production line, a digital model of it is planned and designed in Product Lifecycle Management Software like Process Simulate and Line Design. However, factory work cells undergo iterations of changes in the layout, e.g., introduction of new 3D assets, removal, and modification of existing assets throughout the lifecycle of a production process timeline happen. A factory floor has disparate assets with rich metadata information which interact with each other, yielding a complex environment which is continuously changing in nature throughout the design and operation phase. Therefore, a digital twin representation is often not synchronized w.r.t. as-built representations of the work cell, leading to delays in the work cell design and simulation processes. Current synchronization and verification approaches are manually driven and highly error prone which further delays the time to product and operation.

With the ubiquity and low expense of sensors, now a days it is easier to capture as-built representations of work cells in different data modalities such as images, point-cloud scans and videos. Given current visual observations(images, point-cloud scan) and existing digital twin model(virtual representation), there is a need to keep the factory floor's digital twin up to date by accessing and updating the changes between the real scene and the corresponding digital twin.

Although digital twin synchronization is a vital task, currently there does not exist any automated method to do it efficiently in time bound manner. Spatio-temporal differences in actual sites are accessed manually and then updated in the virtual representation which is followed by consequent steps of verification and validation. Manual synchronization of assets during the design process yields slower times to incremental updates.

Therefore, there is a need for an automated digital twin synchronization with a real production site.

### SUMMARY

Briefly described, aspects of the present invention relate to an automated model-based guided digital twin synchronization system and a method for synchronizing a digital twin representation with a physical 3D scene. Automated digital twin synchronization with a real production site also helps the re-configuration process by updating a in-line designer followed by updating more fine-grained changes in kinematics model representations and model-based attribute information. Thus, such technology will reduce round-trip time in reconfiguration/updates of production facilities and make it economical to reconfigure production facility even for smaller time periods. Automatic digital twin synchronization alleviates human workers from routine inspection jobs(e.g., watching HMI screen to monitor the production), create more high-level human-in-the-loop review and inspection workflows, allowing faster decisions. Piecewise breakdown of mutable scene objects leads to higher accountability, better root cause analysis, and increase digital twin inventory efficiency, reduce design time due to as-planned/as-built differences.

In accordance with one illustrative embodiment of the present invention, an automated model based guided digital twin synchronization system is described. The system comprises one or more visual sensors configured to acquire raw visual data of a physical 3D scene content from a real site in a configurable manner. The system further comprises a database to provide a 3D model of the physical 3D scene content such as a corresponding production line/work cell of assets and large-scale infrastructures. The system further comprises a processor and a memory for storing computer-executable instructions executed by the processor. The instructions comprise an automated machine learning model based logic to:
generate and maintain an as-built digital twin of the assets and large-scale infrastructures present in the physical 3D scene by ingesting the raw visual data to a common and binding structured representation,
compare the as-built digital twin representation obtained from the real site against corresponding an as-planned digital twin to determine spatio-temporal differences between the as-built digital twin and the as-planned digital twin, and
update automatically the as-planned digital twin to reflect any changes to the physical 3D scene based on the spatio-temporal differences.

In accordance with another illustrative embodiment of the present invention, a computer-implemented method of synchronizing a digital twin representation with a physical 3D scene is described. The method is performed by an automated model based guided digital twin synchronization system and comprising:
through operating at least one processor:
acquiring raw visual data of a physical 3D scene content from a real site in a configurable manner;
providing a database to provide a 3D model of the physical 3D scene content such as a corresponding production line/work cell of industrial assets and large-scale infrastructures;
generating and maintaining an as-built digital twin of the assets and large-scale infrastructures present in the physical 3D scene by ingesting the raw visual data to a common and binding structured representation,
comparing the as-built digital twin representation obtained from the real site against corresponding an as-planned digital twin to determine spatio-temporal differences between the as-built digital twin and the as-planned digital twin, and
updating automatically the as-planned digital twin to reflect any changes to the physical 3D scene based on the spatio-temporal differences.

In accordance with another illustrative embodiment of the present invention, a non-transitory computer-readable medium encoded with executable instructions is provided. Instructions executable by at least one processor to operate one or more systems. Instructions, when executed, cause one or more systems to:
acquire raw visual data of a physical 3D scene content from a real site in a configurable manner;
provide a database to provide a 3D model of the physical 3D scene content such as a corresponding production line/work cell of industrial assets and large-scale infrastructures;
generate and maintain an as-built digital twin of the assets and large-scale infrastructures present in the physical 3D scene by ingesting the raw visual data to a common and binding structured representation,
compare the as-built digital twin representation obtained from the real site against corresponding an as-planned digital twin to determine spatio-temporal differences between the as-built digital twin and the as-planned digital twin, and
update automatically the as-planned digital twin to reflect any changes to the physical 3D scene based on the spatio-temporal differences.

### BRIEF DESCRIPTION OF THE DRAWINGS

FIG. 1 illustrates a block diagram of an automated model-based guided digital twin synchronization system in accordance with an exemplary embodiment of the present invention.

FIG. 2 illustrates a block diagram of a workflow of synchronizing digital twins with their real instances based on visual observations in accordance with an exemplary embodiment of the present invention.

FIG. 3 illustrates a block diagram of a method of generating a scene graph by inferring and iteratively refining a physical 3D scene content from visual data (image/point-cloud data), leveraging 3D models in accordance with an exemplary embodiment of the present invention.

FIG. 4 illustrates an overview of the stages of digital-twin synchronization and data workflow in accordance with an exemplary embodiment of the present invention.

FIG. 5 illustrates a schematic view of a flow chart of a method of synchronizing a digital twin representation with a physical 3D scene in an automated model-based guided digital twin synchronization system in accordance with an exemplary embodiment of the present invention.

FIG. 6 shows an example of a computing environment within which embodiments of the disclosure may be implemented.

### DETAILED DESCRIPTION

To facilitate an understanding of embodiments, principles, and features of the present invention, they are explained hereinafter with reference to implementation in illustrative embodiments. In particular, they are described in the context of a system and a method that provides digital-twin synchronization in an automated model-based guided digital twin synchronization system. Embodiments of the present invention, however, are not limited to use in the described devices or methods.

The components and materials described hereinafter as making up the various embodiments are intended to be illustrative and not restrictive. Many suitable components and materials that would perform the same or a similar function as the materials described herein are intended to be embraced within the scope of embodiments of the present invention.

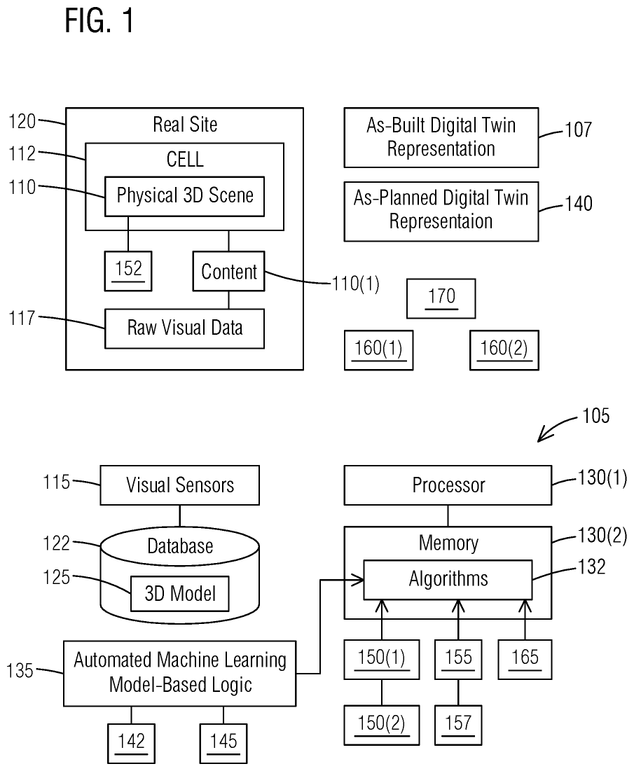

These and other embodiments of an automated model-based guided digital twin synchronization system according to the present disclosure are described below with reference to FIGS. 1-6 herein. Like reference numerals used in the drawings identify similar or identical elements throughout the several views. The drawings are not necessarily drawn to scale.

Consistent with one embodiment of the present invention, FIG. 1 represents a block diagram of an automated model-based guided digital twin synchronization system 105 for synchronizing an as-built digital twin 107 of a physical 3D scene 110 with an as-planned digital twin representation 140 of corresponding production line/work cell 112 in accordance with an exemplary embodiment of the present invention. The automated model based guided digital twin synchronization system 105 reduces a round-trip time in reconfiguration/updates of production facilities and make it economical to reconfigure a production facility even for smaller time periods.

The automated model based guided digital twin synchronization system 105 comprises one or more visual sensors 115 configured to acquire raw visual data 117 of a physical 3D scene content 110(1) from a real site 120 in a configurable manner. The one or more visual sensors 115 comprise mobile/stationary cameras for capturing:(Red, Green, Blue(RGB), depth, Light Detection and Ranging(LIDAR) point-cloud scan of a scene featuring multiple objects of interest).

The automated model based guided digital twin synchronization system 105 further comprises a database 122 to provide a 3D model 125 of the physical 3D scene content 110(1) such as the corresponding production line/work cell 112 of the industrial assets and large-scale infrastructures. The automated model based guided digital twin synchronization system 105 further comprises a processor 130(1) and a memory 130(2) for storing algorithms(e.g., computer-executable instructions) 132 executed by the processor 130(1). The computer-executable instructions 132 comprise an automated machine learning model-based logic 135 that is configured to generate and maintain the as-built digital twin 107 of the industrial assets and large-scale infrastructures present in the physical 3D scene 110 by ingesting the raw visual data 117 to a common and binding structured representation, compare the as-built digital twin 107 obtained from the real site 120 against the as-planned digital twin 140 to determine spatio-temporal differences 142 between the as-planned digital twin 140 and the as-built digital twin 107, and update automatically the as-planned digital twin 140 to reflect any changes to the physical 3D scene 110 based on the spatio-temporal differences 142. The spatio-temporal differences 142 provide a spatio-temporal difference comparison between a physical scene(acquired through RGB/Depth(D) images or point-cloud scan) and its digital twin through a common scene description format.

The automated machine learning model-based logic 135 is configured to generate a scene graph 145 by inferring and iteratively refining the physical 3D scene content 110(1) from the raw visual data 117(image/point-cloud data) by leveraging the 3D model 125. The automated machine learning model-based logic 135 generates the scene graph 145 by predicting the scene graph 145 and enriching the scene graph 145.

The computer-executable instructions 132 further comprise a physical scene encoder 150(1) to create a unified graph-based scene model called the scene graph 145 using machine learning, use Artificial Intelligence(AI)-driven advanced scene understanding to detect objects 152 and their properties from a catalog of known object types, detect inter-object relationships to generate a scene description employing the scene graph 145 as a mode of representation and enhance the scene graph 145 with objects' 3D model information. The computer-executable instructions 132 further comprise a digital scene encoder 150(2) to compress a digital representation in a similar unified scene representation and add metadata fields appended to the detected objects.

The computer-executable instructions 132 further comprise a comparator 155 to employ a graph-based tool 157 to compare assets in a physical representation 160(1) with a virtual representation 160(2) to find any deviations from an as-planned state and provide differences in terms of addition or deletion of objects in a scene and object's pose/position/attribute change. The computer-executable instructions 132 further comprise a validation and update logic 165 to develop a digital model validation and update from detected changes by developing a graphical interface to highlight synchronized changes fed from the comparator 155 stage and after validation, export of all the detected changes is fed into a digital twin model 170 for update such that the detected changes are classified as additions, removals, pose-updates, layout updates and metadata related.

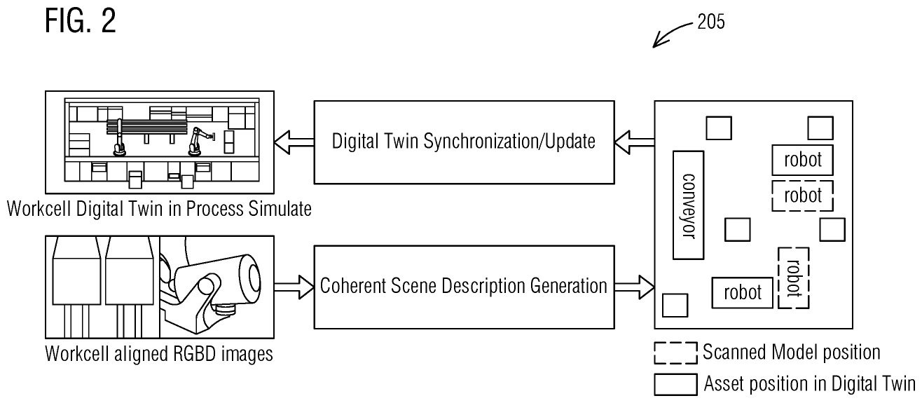

Referring to FIG. 2, it illustrates a block diagram of a workflow 205 of synchronizing digital twins with their real instances based on visual observations in accordance with an exemplary embodiment of the present invention. FIG. 2 demonstrates the spatio-temporal difference comparison between physical scene (acquired through RGB/D images or point-cloud scan) and its digital twin through a common scene description format.

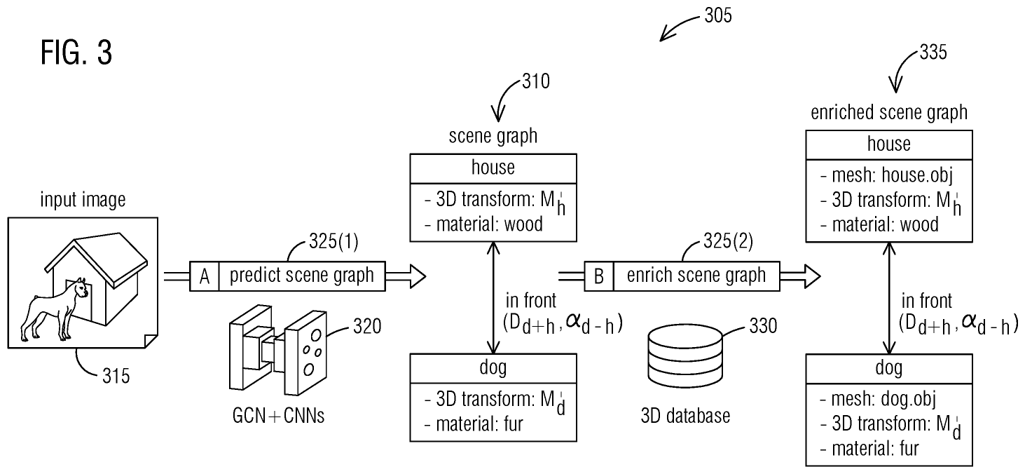

Turning now to FIG. 3, it illustrates a block diagram of a method 305 of generating a scene graph 310 by inferring and iteratively refining a physical 3D scene content from visual data(image/point-cloud data), leveraging 3D models in accordance with an exemplary embodiment of the present invention. FIG. 3 illustrates the steps for scene description generation employing the scene graph 310 as the mode of representation.

An input image 315 is fed into a Graph Convolutional Network(GCN)+Convolutional Neural Networks(CNNs) 320. High-capacity convolutional neural networks(CNNs) are employed to localize and segment objects present in an input image. Such CNN takes an input image, extracts a number of bottom-up category-independent region proposals, computes features for each proposal, and then classifies each region into corresponding object classes. The regression of a physical 3D scene from image(s) is composed of three main steps:(A). scene graph prediction using GCN; (B). 3D properties assignment; and(C). optional scene refinement through differentiable rendering.

Graph Convolutional Network(GCN) is employed to conjointly predict the properties and relationships of object instances detected from input images using CNNs. GCNs decompose complicated computation over graph data into a series of localized operations(typically only involving neighboring nodes) for each node at each time step. The structure and edge strengths are typically fixed prior to the computation. The GCN is helpful in refining the node and relationship representations by propagating context between nodes in candidate scene graphs emphasizing on both visual and semantic features.

The Graph Convolutional Network(GCN)+Convolutional Neural Networks (CNNs) 320 predict the scene graph 310 in a step 325(1). In a next step 325(2), the scene graph 310 is enriched using a 3D database 330 to provide an enriched scene graph 335.

In FIG. 3, underneath the term “in front” the distance and pose transformation is indicated between the two representative objects: ‘House’ and ‘Dog’.

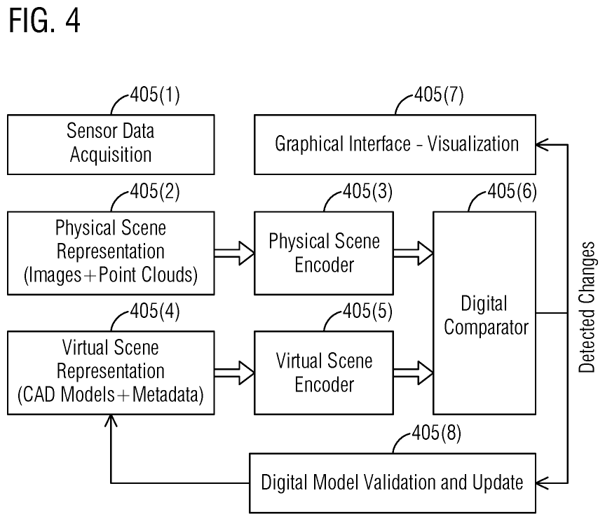

FIG. 4 illustrates an overview of stages 405(1-8) of digital-twin synchronization and data workflow in accordance with an exemplary embodiment of the present invention. In sensor data acquisition stage 405(1), from a real site, acquire data from visual sensors in a configurable manner using mobile/stationary cameras(RGB, depth, LIDAR point-cloud scan of a scene featuring multiple objects of interest). Get a 3D model of a corresponding 20 m×10 m production line/work cell.

For physical scene representation stage 405(2), a physical scene encoder stage 405(3) is provided. It, using machine learning, creates a unified graph-based scene model for representing what today is represented in heterogenous modalities(RGB images, point-clouds, depth images, CAD models). It uses AI-driven advanced scene understanding to detect objects and their properties from a catalog of known object types (object identity, position, features, pose). Detect inter-object relationships to generate a scene description.

For virtual scene representation stage 405(4), a virtual scene encoder stage 405(5) is provided. It compresses the digital representation in a similar unified scene representation and adds metadata fields appended to detected objects.

A digital comparator stage 405(6) employs a graph-based tool to compare the assets in the physical representation with the virtual representation to find any deviations from the as-planned state. Provide differences in terms of addition or deletion of objects in a scene, object's pose/position/attribute change.

A graphical interface-visualization stage 405(7) develops a graphical interface to highlight synchronized changes fed from the digital comparator stage 405(6). A digital model validation and update stage 405(8), once validated by a subject matter expert, feeds export of all such changes into the digital twin model for update. Changes are classified as additions, removals, pose-updates, layout updates and metadata related.

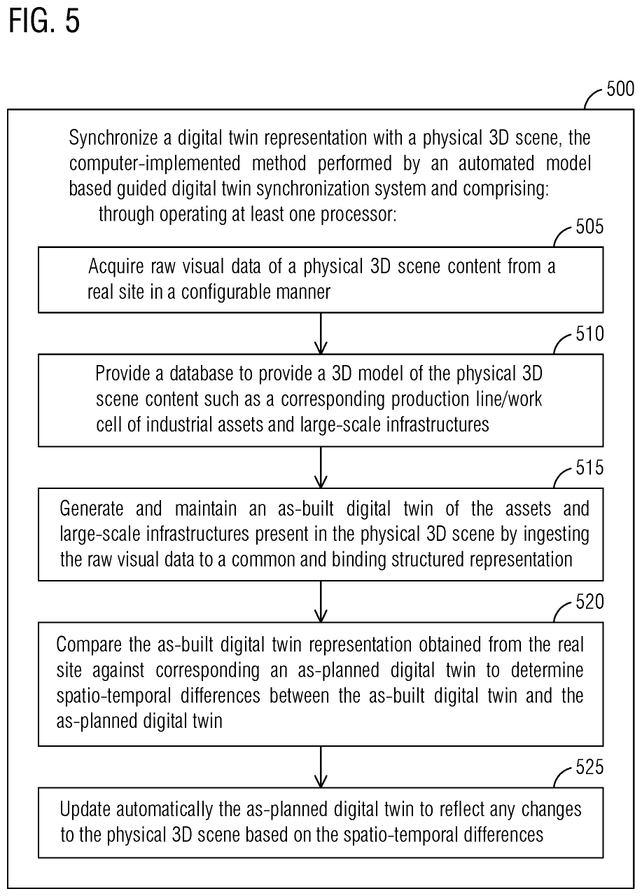

FIG. 5 illustrates a schematic view of a flow chart of a computer-implemented method 500 of synchronizing a digital twin representation with a physical 3D scene by an automated model-based guided digital twin synchronization system in accordance with an exemplary embodiment of the present invention. Reference is made to the elements and features described in FIGS. 1-4. It should be appreciated that some steps are not required to be performed in any particular order, and that some steps are optional.

The method 500 performed by an automated model-based guided digital twin synchronization system through operating at least one processor comprises a step 505 of providing acquiring raw visual data of a physical 3D scene content from a real site in a configurable manner. The method 500 further comprises a step 510 of providing a database to provide a 3D model of the physical 3D scene content such as a corresponding production line/work cell of industrial assets and large-scale infrastructures. The method 500 further comprises a step 515 of generating and maintaining an as-built digital twin of the industrial assets and large-scale infrastructures present in a physical 3D scene by ingesting the raw visual data to a common and binding structured representation. The method 500 further comprises a step 520 of comparing the as-built digital twin representation obtained from the real site against the as-planned digital twin to determine spatio-temporal differences between the as-built and as-planned digital twins. The method 500 further comprises a step 525 of updating automatically the as-planned digital twin to reflect any changes to the physical 3D scene based on the spatio-temporal differences.

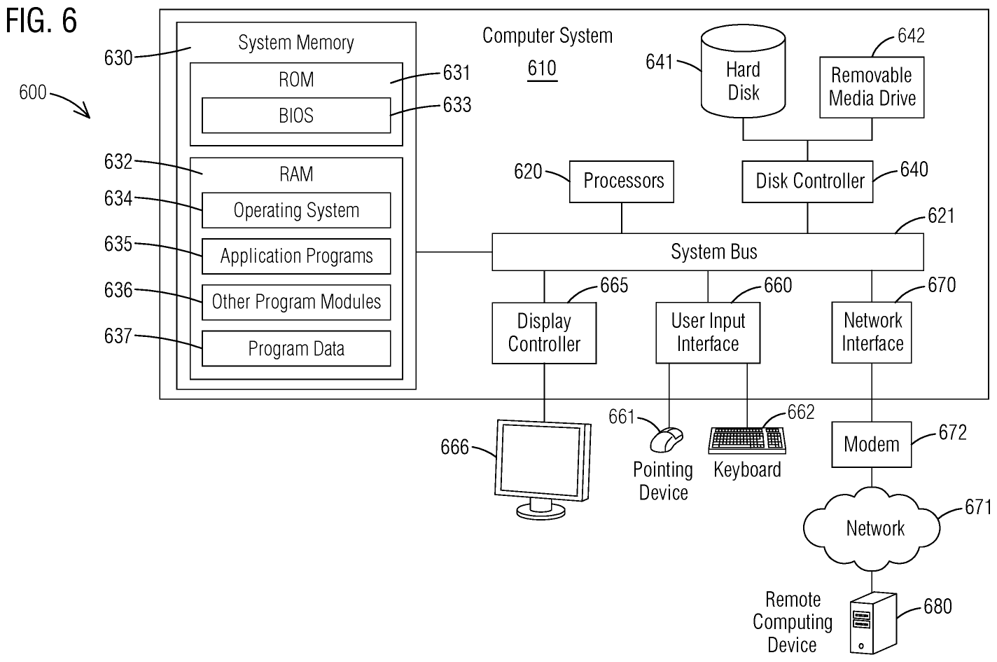

FIG. 6 shows an example of a computing environment within which embodiments of the disclosure may be implemented. For example, this computing environment 600 may be configured to execute the automated model-based guided digital twin synchronization system discussed above with reference to FIG. 1 or to execute portions of the method 600 described above with respect to FIG. 5. Computers and computing environments, such as computer system 610 and computing environment 600, are known to those of skill in the art and thus are described briefly here.

As shown in FIG. 6, the computer system 610 may include a communication mechanism such as a bus 621 or other communication mechanism for communicating information within the computer system 610. The computer system 610 further includes one or more processors 620 coupled with the bus 621 for processing the information. The processors 620 may include one or more central processing units(CPUs), graphical processing units(GPUs), or any other processor known in the art.

The computer system 610 also includes a system memory 630 coupled to the bus 621 for storing information and instructions to be executed by processors 620. The system memory 630 may include computer readable storage media in the form of volatile and/or nonvolatile memory, such as read only memory(ROM) 631 and/or random access memory(RAM) 632. The system memory RAM 632 may include other dynamic storage device(s)(e.g., dynamic RAM, static RAM, and synchronous DRAM). The system memory ROM 631 may include other static storage device(s)(e.g., programmable ROM, erasable PROM, and electrically erasable PROM). In addition, the system memory 630 may be used for storing temporary variables or other intermediate information during the execution of instructions by the processors 620. A basic input/output system(BIOS) 633 containing the basic routines that helps to transfer information between elements within computer system 610, such as during start-up, may be stored in ROM 631. RAM 632 may contain data and/or program modules that are immediately accessible to and/or presently being operated on by the processors 620. System memory 630 may additionally include, for example, operating system 634, application programs 635, other program modules 636 and program data 637.

The computer system 610 also includes a disk controller 640 coupled to the bus 621 to control one or more storage devices for storing information and instructions, such as a hard disk 641 and a removable media drive 642(e.g., floppy disk drive, compact disc drive, tape drive, and/or solid state drive). The storage devices may be added to the computer system 610 using an appropriate device interface(e.g., a small computer system interface(SCSI), integrated device electronics(IDE), Universal Serial Bus(USB), or FireWire).

The computer system 610 may also include a display controller 665 coupled to the bus 621 to control a display 666, such as a cathode ray tube(CRT) or liquid crystal display(LCD), for displaying information to a computer user. The computer system includes an input interface 660 and one or more input devices, such as a keyboard 662 and a pointing device 661, for interacting with a computer user and providing information to the processor 620. The pointing device 661, for example, may be a mouse, a trackball, or a pointing stick for communicating direction information and command selections to the processor 620 and for controlling cursor movement on the display 666. The display 666 may provide a touch screen interface which allows input to supplement or replace the communication of direction information and command selections by the pointing device 661.

The computer system 610 may perform a portion or all of the processing steps of embodiments of the invention in response to the processors 620 executing one or more sequences of one or more instructions contained in a memory, such as the system memory 630. Such instructions may be read into the system memory 630 from another computer readable medium, such as a hard disk 641 or a removable media drive 642. The hard disk 641 may contain one or more datastores and data files used by embodiments of the present invention. Datastore contents and data files may be encrypted to improve security. The processors 620 may also be employed in a multi-processing arrangement to execute the one or more sequences of instructions contained in system memory 630. In alternative embodiments, hard-wired circuitry may be used in place of or in combination with software instructions. Thus, embodiments are not limited to any specific combination of hardware circuitry and software.

As stated above, the computer system 610 may include at least one computer readable medium or memory for holding instructions programmed according to embodiments of the invention and for containing data structures, tables, records, or other data described herein. The term “computer readable medium” as used herein refers to any medium that participates in providing instructions to the processor 620 for execution. A computer readable medium may take many forms including, but not limited to, non-volatile media, volatile media, and transmission media. Non-limiting examples of non-volatile media include optical disks, solid state drives, magnetic disks, and magneto-optical disks, such as hard disk 641 or removable media drive 642. Non-limiting examples of volatile media include dynamic memory, such as system memory 630. Non-limiting examples of transmission media include coaxial cables, copper wire, and fiber optics, including the wires that make up the bus 621. Transmission media may also take the form of acoustic or light waves, such as those generated during radio wave and infrared data communications.

The computing environment 600 may further include the computer system 610 operating in a networked environment using logical connections to one or more remote computers, such as remote computer 680. Remote computer 680 may be a personal computer(laptop or desktop), a mobile device, a server, a router, a network PC, a peer device or other common network node, and typically includes many or all of the elements described above relative to computer system 610. When used in a networking environment, computer system 610 may include modem 672 for establishing communications over a network 671, such as the Internet. Modem 672 may be connected to bus 621 via user network interface 670, or via another appropriate mechanism.

Network 671 may be any network or system generally known in the art, including the Internet, an intranet, a local area network(LAN), a wide area network (WAN), a metropolitan area network(MAN), a direct connection or series of connections, a cellular telephone network, or any other network or medium capable of facilitating communication between computer system 610 and other computers(e.g., remote computer 680). The network 671 may be wired, wireless or a combination thereof. Wired connections may be implemented using Ethernet, Universal Serial Bus (USB), RJ-11 or any other wired connection generally known in the art. Wireless connections may be implemented using Wi-Fi, WiMAX, and Bluetooth, infrared, cellular networks, satellite or any other wireless connection methodology generally known in the art. Additionally, several networks may work alone or in communication with each other to facilitate communication in the network 671.

In some embodiments, the computer system 610 may be utilized in conjunction with a parallel processing platform comprising a plurality of processing units. This platform may allow parallel execution of one or more of the tasks associated with optimal design generation, as described above. For the example, in some embodiments, execution of multiple product lifecycle simulations may be performed in parallel, thereby allowing reduced overall processing times for optimal design selection.

The embodiments of the present disclosure may be implemented with any combination of hardware and software. In addition, the embodiments of the present disclosure may be included in an article of manufacture(e.g., one or more computer program products) having, for example, computer-readable, non-transitory media. The media has embodied therein, for instance, computer readable program code for providing and facilitating the mechanisms of the embodiments of the present disclosure. The article of manufacture can be included as part of a computer system or sold separately.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

An executable application, as used herein, comprises code or machine readable instructions for conditioning the processor to implement predetermined functions, such as those of an operating system, a context data acquisition system or other information processing system, for example, in response to user command or input. An executable procedure is a segment of code or machine readable instruction, sub-routine, or other distinct section of code or portion of an executable application for performing one or more particular processes. These processes may include receiving input data and/or parameters, performing operations on received input data and/or performing functions in response to received input parameters, and providing resulting output data and/or parameters.

A graphical user interface(GUI), as used herein, comprises one or more display images, generated by a display processor and enabling user interaction with a processor or other device and associated data acquisition and processing functions. The GUI also includes an executable procedure or executable application. The executable procedure or executable application conditions the display processor to generate signals representing the GUI display images. These signals are supplied to a display device which displays the image for viewing by the user. The processor, under control of an executable procedure or executable application, manipulates the GUI display images in response to signals received from the input devices. In this way, the user may interact with the display image using the input devices, enabling user interaction with the processor or other device.

The functions and process steps herein may be performed automatically or wholly or partially in response to user command. An activity(including a step) performed automatically is performed in response to one or more executable instructions or device operation without user direct initiation of the activity.

The system and processes of the figures are not exclusive. Other systems, processes and menus may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention. As described herein, the various systems, subsystems, agents, managers and processes can be implemented using hardware components, software components, and/or combinations thereof.

Computer readable medium instructions for carrying out operations of the present disclosure may be assembler instructions, instruction-set-architecture(ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network(LAN) or a wide area network(WAN), or the connection may be made to an external computer(for example, through the Internet using an Internet Service Provider). In some embodiments, electronic circuitry including, for example, programmable logic circuitry, field-programmable gate arrays(FPGA), or programmable logic arrays(PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus(systems), and computer program products according to embodiments of the disclosure. It will be understood that each block of the flowchart illustrations and/or block diagrams, and combinations of blocks in the flowchart illustrations and/or block diagrams, may be implemented by computer readable medium instructions.

It should be appreciated that the program modules, applications, computer-executable instructions, code, or the like depicted in FIG. 6 as being stored in the system memory are merely illustrative and not exhaustive and that processing described as being supported by any particular module may alternatively be distributed across multiple modules or performed by a different module. In addition, various program module(s), script(s), plug-in(s), Application Programming Interface(s)(API(s)), or any other suitable computer-executable code hosted locally on the computer system 610, the remote device, and/or hosted on other computing device(s) accessible via one or more of the network(s), may be provided to support functionality provided by the program modules, applications, or computer-executable code depicted in FIG. 6 and/or additional or alternate functionality. Further, functionality may be modularized differently such that processing described as being supported collectively by the collection of program modules depicted in FIG. 6 may be performed by a fewer or greater number of modules, or functionality described as being supported by any particular module may be supported, at least in part, by another module. In addition, program modules that support the functionality described herein may form part of one or more applications executable across any number of systems or devices in accordance with any suitable computing model such as, for example, a client-server model, a peer-to-peer model, and so forth. In addition, any of the functionality described as being supported by any of the program modules depicted in FIG. 6 may be implemented, at least partially, in hardware and/or firmware across any number of devices.

It should further be appreciated that the computer system 610 may include alternate and/or additional hardware, software, or firmware components beyond those described or depicted without departing from the scope of the disclosure. More particularly, it should be appreciated that software, firmware, or hardware components depicted as forming part of the computer system 610 are merely illustrative and that some components may not be present or additional components may be provided in various embodiments. While various illustrative program modules have been depicted and described as software modules stored in system memory, it should be appreciated that functionality described as being supported by the program modules may be enabled by any combination of hardware, software, and/or firmware. It should further be appreciated that each of the above-mentioned modules may, in various embodiments, represent a logical partitioning of supported functionality. This logical partitioning is depicted for ease of explanation of the functionality and may not be representative of the structure of software, hardware, and/or firmware for implementing the functionality. Accordingly, it should be appreciated that functionality described as being provided by a particular module may, in various embodiments, be provided at least in part by one or more other modules. Further, one or more depicted modules may not be present in certain embodiments, while in other embodiments, additional modules not depicted may be present and may support at least a portion of the described functionality and/or additional functionality. Moreover, while certain modules may be depicted and described as sub-modules of another module, in certain embodiments, such modules may be provided as independent modules or as sub-modules of other modules.

Although specific embodiments of the disclosure have been described, one of ordinary skill in the art will recognize that numerous other modifications and alternative embodiments are within the scope of the disclosure. For example, any of the functionality and/or processing capabilities described with respect to a particular device or component may be performed by any other device or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure. In addition, it should be appreciated that any operation, element, component, data, or the like described herein as being based on another operation, element, component, data, or the like can be additionally based on one or more other operations, elements, components, data, or the like. Accordingly, the phrase “based on,” or variants thereof, should be interpreted as “based at least in part on.”

Although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While “a physical 3D scene content” and “a 3D model” are described here a range of one or more other types of dimensions or other forms of content/model are also contemplated by the present invention. For example, other types of dimensions may be implemented based on one or more features presented above without deviating from the spirit of the present invention.

The techniques described herein can be particularly useful for automated model based guided systems. While particular embodiments are described in terms of the an automated model based guided system, the techniques described herein are not limited to automated model based guided system but can also be used with other systems.

While embodiments of the present invention have been disclosed in exemplary forms, it will be apparent to those skilled in the art that many modifications, additions, and deletions can be made therein without departing from the spirit and scope of the invention and its equivalents, as set forth in the following claims.

Embodiments and the various features and advantageous details thereof are explained more fully with reference to the non-limiting embodiments that are illustrated in the accompanying drawings and detailed in the following description. Descriptions of well-known starting materials, processing techniques, components and equipment are omitted so as not to unnecessarily obscure embodiments in detail. It should be understood, however, that the detailed description and the specific examples, while indicating preferred embodiments, are given by way of illustration only and not by way of limitation. Various substitutions, modifications, additions and/or rearrangements within the spirit and/or scope of the underlying inventive concept will become apparent to those skilled in the art from this disclosure.

As used herein, the terms “comprises,” “comprising,” “includes,” “including,” “has,” “having” or any other variation thereof, are intended to cover a non-exclusive inclusion. For example, a process, article, or apparatus that comprises a list of elements is not necessarily limited to only those elements but may include other elements not expressly listed or inherent to such process, article, or apparatus.

Additionally, any examples or illustrations given herein are not to be regarded in any way as restrictions on, limits to, or express definitions of, any term or terms with which they are utilized. Instead, these examples or illustrations are to be regarded as being described with respect to one particular embodiment and as illustrative only. Those of ordinary skill in the art will appreciate that any term or terms with which these examples or illustrations are utilized will encompass other embodiments which may or may not be given therewith or elsewhere in the specification and all such embodiments are intended to be included within the scope of that term or terms.

In the foregoing specification, the invention has been described with reference to specific embodiments. However, one of ordinary skill in the art appreciates that various modifications and changes can be made without departing from the scope of the invention. Accordingly, the specification and figures are to be regarded in an illustrative rather than a restrictive sense, and all such modifications are intended to be included within the scope of invention.

Although the invention has been described with respect to specific embodiments thereof, these embodiments are merely illustrative, and not restrictive of the invention. The description herein of illustrated embodiments of the invention is not intended to be exhaustive or to limit the invention to the precise forms disclosed herein (and in particular, the inclusion of any particular embodiment, feature or function is not intended to limit the scope of the invention to such embodiment, feature or function). Rather, the description is intended to describe illustrative embodiments, features and functions in order to provide a person of ordinary skill in the art context to understand the invention without limiting the invention to any particularly described embodiment, feature or function. While specific embodiments of, and examples for, the invention are described herein for illustrative purposes only, various equivalent modifications are possible within the spirit and scope of the invention, as those skilled in the relevant art will recognize and appreciate. As indicated, these modifications may be made to the invention in light of the foregoing description of illustrated embodiments of the invention and are to be included within the spirit and scope of the invention. Thus, while the invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the invention.

Respective appearances of the phrases “in one embodiment,” “in an embodiment,” or “in a specific embodiment” or similar terminology in various places throughout this specification are not necessarily referring to the same embodiment. Furthermore, the particular features, structures, or characteristics of any particular embodiment may be combined in any suitable manner with one or more other embodiments. It is to be understood that other variations and modifications of the embodiments described and illustrated herein are possible in light of the teachings herein and are to be considered as part of the spirit and scope of the invention.

In the description herein, numerous specific details are provided, such as examples of components and/or methods, to provide a thorough understanding of embodiments of the invention. One skilled in the relevant art will recognize, however, that an embodiment may be able to be practiced without one or more of the specific details, or with other apparatus, systems, assemblies, methods, components, materials, parts, and/or the like. In other instances, well-known structures, components, systems, materials, or operations are not specifically shown or described in detail to avoid obscuring aspects of embodiments of the invention. While the invention may be illustrated by using a particular embodiment, this is not and does not limit the invention to any particular embodiment and a person of ordinary skill in the art will recognize that additional embodiments are readily understandable and are a part of this invention.

It will also be appreciated that one or more of the elements depicted in the drawings/figures can also be implemented in a more separated or integrated manner, or even removed or rendered as inoperable in certain cases, as is useful in accordance with a particular application.

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component.

What is claimed is:

1. An automated model based guided digital twin synchronization system, the system comprising:
one or more visual sensors configured to acquire raw visual data of a physical 3D scene content from a real site in a configurable manner;
a database to provide a 3D model of the physical 3D scene content such as a corresponding production line/work cell of industrial assets and large-scale infrastructures;
a processor; and
a memory for storing computer-executable instructions executed by the processor, wherein the instructions comprise an automated machine learning model based logic to:
generate and maintain an as-built digital twin of the assets and large-scale infrastructures present in the physical 3D scene by ingesting the raw visual data to a common and binding structured representation,
compare the as-built digital twin representation obtained from the real site against corresponding an as-planned digital twin to determine spatio-temporal differences between the as-built digital twin and the as-planned digital twin, and
update automatically the as-planned digital twin to reflect any changes to the physical 3D scene based on the spatio-temporal differences.

2. The automated model based guided digital twin synchronization system of claim 1, wherein the automated machine learning model based logic to:
generate a scene graph by inferring and iteratively refining the physical 3D scene content from the raw visual data(image/point-cloud data) by leveraging the 3D model.

3. The automated model based guided digital twin synchronization system of claim 2, wherein the automated machine learning model based logic to:
generate the scene graph by predicting the scene graph and enriching the scene graph.

4. The automated model based guided digital twin synchronization system of claim 3, wherein the instructions comprise a physical scene encoder to:
create a unified graph-based scene model called the scene graph using machine learning;
use Artificial Intelligence(AI)-driven advanced scene understanding to detect objects and their properties from a catalog of known object types;
detect inter-object relationships to generate a scene description employing the scene graph as a mode of representation; and
enhance the scene graph with objects' 3D model information.

5. The automated model based guided digital twin synchronization system of claim 4, wherein the instructions comprise a digital scene encoder to:
compress a digital representation in a similar unified scene representation; and
add metadata fields appended to the detected objects.

6. The automated model based guided digital twin synchronization system of claim 5, wherein the instructions comprise a comparator to:
employ a graph-based tool to compare assets in a physical representation with a virtual representation to find any deviations from an as-planned state; and
provide differences in terms of addition or deletion of objects in a scene and object's pose/position/attribute change.

7. The automated model based guided digital twin synchronization system of claim 6, wherein the instructions comprise a validation and update logic to:
develop a digital model validation and update from detected changes by developing a graphical interface to highlight synchronized changes fed from a comparator stage; and
after validation, export of all the detected changes is fed into a digital twin model for update such that the detected changes are classified as additions, removals, pose-updates, layout updates and metadata related.

8. The automated model based guided digital twin synchronization system of claim 1, wherein the one or more visual sensors comprise mobile/stationary cameras for capturing:(Red, Green, Blue(RGB), depth, Light Detection and Ranging(LIDAR) point-cloud scan of a scene featuring multiple objects of interest).

9. The automated model based guided digital twin synchronization system of claim 1, wherein the spatio-temporal differences provide a spatio-temporal difference comparison between a physical scene(acquired through RGB/Depth(D) images or point-cloud scan) and its digital twin through a common scene description format.

10. The automated model based guided digital twin synchronization system of claim 1, wherein the system reduces a round-trip time in reconfiguration/updates of production facilities and make it economical to reconfigure a production facility even for smaller time periods.

11. A computer-implemented method of synchronizing a digital twin representation with a physical 3D scene, the method performed by an automated model based guided digital twin synchronization system and comprising:
through operating at least one processor:
acquiring raw visual data of a physical 3D scene content from a real site in a configurable manner;
providing a database to provide a 3D model of the physical 3D scene content such as a corresponding production line/work cell of industrial assets and large-scale infrastructures;
generating and maintaining an as-built digital twin of the assets and large-scale infrastructures present in the physical 3D scene by ingesting the raw visual data to a common and binding structured representation;
comparing the as-built digital twin representation obtained from the real site against corresponding an as-planned digital twin to determine spatio-temporal differences between the as-built digital twin and the as-planned digital twin; and
updating automatically the as-planned digital twin to reflect any changes to the physical 3D scene based on the spatio-temporal differences.

12. The computer-implemented method of claim 11, wherein an automated machine learning model based logic to:
generate a scene graph by inferring and iteratively refining the physical 3D scene content from the raw visual data(image/point-cloud data) by leveraging the 3D model.

13. The computer-implemented method of claim 12, wherein the automated machine learning model based logic to:
generate the scene graph by predicting the scene graph and enriching the scene graph.

14. The computer-implemented method of claim 13, wherein a physical scene encoder to:
create a unified graph-based scene model called the scene graph using machine learning;
use Artificial Intelligence(AI)-driven advanced scene understanding to detect objects and their properties from a catalog of known object types;
detect inter-object relationships to generate a scene description employing the scene graph as a mode of representation; and
enhance the scene graph with objects' 3D model information.

15. The computer-implemented method of claim 14, wherein a digital scene encoder to:
compress a digital representation in a similar unified scene representation; and
add metadata fields appended to the detected objects.

16. The computer-implemented method of claim 15, wherein a comparator to:
employ a graph-based tool to compare assets in a physical representation with a virtual representation to find any deviations from an as-planned state; and
provide differences in terms of addition or deletion of objects in a scene and object's pose/position/attribute change.

17. The computer-implemented method of claim 6, wherein a validation and update logic to:
develop a digital model validation and update from detected changes by developing a graphical interface to highlight synchronized changes fed from a comparator stage; and
after validation, export of all the detected changes is fed into a digital twin model for update such that the detected changes are classified as additions, removals, pose-updates, layout updates and metadata related.

18. The computer-implemented method of claim 11, further comprising:
using one or more visual sensors including mobile/stationary cameras for capturing:(Red, Green, Blue(RGB), depth, Light Detection and Ranging(LIDAR) point-cloud scan of a scene featuring multiple objects of interest); and
reducing a round-trip time in reconfiguration/updates of production facilities for making it economical to reconfigure a production facility even for smaller time periods, wherein the spatio-temporal differences provide a spatio-temporal difference comparison between a physical scene(acquired through RGB/Depth(D) images or point-cloud scan) and its digital twin through a common scene description format.

19. A non-transitory computer-readable storage medium encoded with instructions executable by at least one processor to operate one or more systems, the instructions comprising:
acquire raw visual data of a physical 3D scene content from a real site in a configurable manner;
provide a database to provide a 3D model of the physical 3D scene content such as a corresponding production line/work cell of industrial assets and large-scale infrastructures;
generate and maintain an as-built digital twin of the assets and large-scale infrastructures present in the physical 3D scene by ingesting the raw visual data to a common and binding structured representation;
compare the as-built digital twin representation obtained from the real site against corresponding an as-planned digital twin to determine spatio-temporal differences between the as-built digital twin and the as-planned digital twin; and
update automatically the as-planned digital twin to reflect any changes to the physical 3D scene based on the spatio-temporal differences.

20. The computer-readable medium of claim 19, wherein the instructions further comprising an automated machine learning model based logic to:
generate a scene graph by inferring and iteratively refining the physical 3D scene content from the raw visual data(image/point-cloud data) by leveraging the 3D model.
